(19) United States
(12) Patent Application Publication
(10) Pub. No.: US 2025/0077747 A1
(43) Pub. Date: Mar. 6, 2025

(54) AUTOMATED REAL-TIME DETERMINATION OF SIGNAL STRENGTH IN WELL-TEST DATA

(71) Applicant: Saudi Arabian Oil Company, Dhahran (SA)

(72) Inventor: Noor M. Anisur Rahman, Dhahran (SA)

(21) Appl. No.: 18/456,935

(22) Filed: Aug. 28, 2023

(51) Int. Cl. G06F 30/28; E21B 47/06; G01V 9/00; G01V 99/00

(52) U.S. Cl. CPC G06F 30/28; E21B 47/06; G01V 9/00; G01V 20/00; E21B 2200/20

(57) ABSTRACT

System and methods include performing a well test on a well, the well comprising a subterranean wellbore with a tubular. The computer system can receive raw data from a pressure gauge residing within the tubular, the raw data comprising discrete pressure values in a time series for a fluid flowing through the tubular. From the raw data, the computer system can determine an amplitude of noise for each pressure value in a time series and derive signal-to-noise ratio (SNR) for each pressure value in a time series based on the determined amplitude. The SNR can be compared against a predetermined threshold value. When SNR is above the threshold, a simulation of the well can be constructed to forecast well production rates. If SNR is below the threshold, corrective action can be taken to improve SNR of pressure values read from a sensor in the well.

### TECHNICAL FIELD

This disclosure pertains to automated real-time determination of signal strength for well-test data.

### BACKGROUND

Well tests are to evaluate performance parameters of the well and the reservoir with measured production rates, and downhole pressures under field-operating conditions. Combining rate, pressure, fluid and petrophysical properties, a set of diagnostic semi-log and log-log plots is created to visualize the flow mechanisms in the well and the reservoir. From these plots, diagnostic flow regimes are identified to ascertain if the data is dominated by the infinite-acting radial or the reservoir-dominated flow. Under such conditions, in-situ reservoir properties as transmissibility, flow capacity and effective permeability in the reservoir around the well can be determined. These important parameters later become input to the full-field reservoir simulation model, which makes the forecast of future production rates for economic analysis. In addition, average reservoir pressure, skin factor, productivity index, and distance to boundaries are estimated.

### SUMMARY

The present disclosure describes techniques that can be used for accurately evaluating well test data.

Aspects of the implementations are directed to a computer-implemented method that includes performing a well test on a well. The well can include a subterranean wellbore with a tubular; receiving by a computer system, raw data from a pressure gauge residing within the tubular. The raw data comprising discrete pressure values in a time series for a fluid flowing through the tubular; determining, by the computer system, an amplitude of noise for each pressure value in a time series; computing, by the computer system, signal-to-noise ratio for each pressure value in a time series based on the determined amplitude; comparing, by the computer system, the signal-to-noise ratio against a predetermined threshold value for each pressure value in a time series; for each pressure value in a time series, determining, by the computer system, whether the signal-to-noise ratio is above or below the predetermined threshold value; constructing, by the computer system, a simulation of the well based on the signal-to-noise ratio for each pressure value in a time series being above the predetermined threshold value; and forecasting, by the computer system, future production rates for the well using the simulation.

Some implementations include, for each pressure value in a time series, determining, by the computer system, that the signal-to-noise ratio is below the predetermined threshold value; and for each pressure value in a time series, performing a corrective action to address the signal-to-noise ratio being below the predetermined threshold value.

In some implementations, the corrective action can include one or more of adjusting to higher production or injection rates for higher drawdown in the reservoir; controlling operational noise; scheduling to minimize impacts of tides in offshore fields; avert multi-phase flow of fluids; deploying gauges with better resolution; adjusting test duration; keeping longer flow or injection periods; placing gauges close to reservoir; and minimizing wellbore dynamics during shut in.

Some implementations can include defining a sampling window W to establish a subset of raw data for calculating signal-to-noise ratio for the pressure value in a time series.

Some implementations can include an assumed pressure of the well in a time series, determining maximum and minimum values of the pressure value in a time series for pressure values within the window W, and wherein determining the amplitude of the noise comprises determining the amplitude of the noise from the minimum and maximum pressure values within the window W.

Some implementations can include constructing a log-log plot of a pressure derivative profile based on the determined signal-to-noise ratio for each pressure value in a time series.

Some implementations can include performing a pressure-transient analysis using the pressure derivate profile.

Aspects of the implementations are directed to a non-transitory, computer-readable medium storing one or more instructions executable by a computer system to perform operations that include performing a well test on a well. The well can include a subterranean wellbore with a tubular; receiving, by a computer system, raw data from a pressure gauge residing within the tubular, the raw data comprising a pressure value in a time series for a fluid flowing through the tubular; determining, by the computer system, an amplitude of noise for each pressure value in a time series; computing, by the computer system, signal-to-noise ratio for each pressure value in a time series based on the determined amplitude; comparing, by the computer system, the signal-to-noise ratio against a predetermined threshold value for each pressure value in a time series; for each pressure value in a time series, determining, by the computer system, whether the signal-to-noise ratio is above or below the predetermined threshold value; and constructing, by the computer system, a simulation of the well based on the signal-to-noise ratio for each pressure value in a time series being above the predetermined threshold value; and forecasting, by the computer system, future production rates for the well using the simulation.

Some implementations can include, for each pressure value in a time series, determining, by the computer system, that the signal-to-noise ratio is below the predetermined threshold value; and for each pressure value in a time series, performing a corrective action to address the signal-to-noise ratio being below the predetermined threshold value.

Some implementations can include operations to adjust to higher production or injection rates for higher drawdown in the reservoir; control operational noise; schedule to minimize impacts of tides in offshore fields; avert multi-phase flow of fluids; deploy gauges with better resolution; adjust test duration; keep longer flow or injection periods; place gauges close to reservoir; and minimize wellbore dynamics during shut in.

Some implementations can include defining a sampling window W to establish a subset of raw data for calculating signal-to-noise ratio for the pressure value in a time series.

Some implementations can include an assumed initial or average reservoir pressure of the well corresponding to the discrete pressure data in a time series, determining maximum and minimum values of the pressure value in a time series for pressure values within the window W, and wherein determining the amplitude of the noise comprises determining the amplitude of the noise from the minimum and maximum pressure values within the window W.

Some implementations can include constructing a log-log plot of a pressure derivative profile based on the determined signal-to-noise ratio for each pressure value in a time series.

Some implementations can include performing a pressure-transient analysis using the pressure derivate profile.

Aspects of the implementations are directed to a computer-implemented system that includes one or more processors; and a non-transitory computer-readable storage medium coupled to the one or more processors and storing programming instructions for execution by the one or more processors, the programming instructions instructing the one or more processors to perform operations. The operations can include performing a well test on a well, the well comprising of a subterranean wellbore with a tubular; receiving, by a computer system, raw data from a pressure gauge residing within the tubular, the raw data comprising a pressure value in a time series for a fluid flowing through the tubular; determining, by the computer system, an amplitude of noise for each pressure value in a time series; computing, by the computer system, signal-to-noise ratio for each pressure value in a time series based on the determined amplitude; comparing, by the computer system, the signal-to-noise ratio against a predetermined threshold value for each pressure value in a time series; for each pressure value in a time series, determining, by the computer system, whether the signal-to-noise ratio is above or below the predetermined threshold value; and constructing, by the computer system, a simulation of the well based on the signal-to-noise ratio for each pressure value in a time series being above the predetermined threshold value; performing pressure-transient analysis with the raw pressure data in a time series; computing well and reservoir parameters; building a reservoir simulation with the well and reservoir parameters as input; and forecasting, by the computer system, future production rates for the well using the simulation.

Some implementations can include for each pressure value in a time series, determining, by the computer system, that the signal-to-noise ratio is below the predetermined threshold value; and for each pressure value in a time series, performing a corrective action to address the signal-to-noise ratio being below the predetermined threshold value.

Some implementations can include one or more operations to adjust to higher production or injection rates for higher drawdown in the reservoir; control operational noise; schedule to minimize impacts of tides in offshore fields; avert multi-phase flow of fluids; deploy gauges with better resolution; adjust test duration; keep longer flow or injection periods; place gauges close to reservoir; or minimize wellbore dynamics during shut in.

Some implementations can include defining a sampling window W to establish a subset of raw data for calculating signal-to-noise ratio for the pressure value in a time series.

Some implementations can include for a measured pressure of the well in a time series, determining maximum and minimum values of the pressure values in a time series for pressure values within the window W, and wherein determining the amplitude of the noise comprises determining the amplitude of the noise from the minimum and maximum pressure values within the window W.

Some implementations can include constructing a log-log plot of a pressure derivative profile based on the determined signal-to-noise ratio for each pressure value in a time series; and performing a pressure-transient analysis using the pressure derivate profile.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method/the instructions stored on the non-transitory, computer-readable medium.

The subject matter described in this specification can be implemented in particular implementations, so as to realize advantages that are readily apparent. This disclosure proposes a preemptive approach that would trigger a corrective measure to avert any further loss of pressure data due to low signal-to-noise ratios. The method is equally application to investigate why a given set of historical pressure data from a previous test has failed to demonstrate a definite trend of pressure derivative on a log-log plot by quantifying the embedded signal-to-noise ratios in the pressure data. For example, among the numerous advantages are maintaining increased accuracy of well test data and increase efficiency of processing the well test data. This method provides a systematic tool to quantify the noise level in the pressure data.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### BRIEF DESCRIPTION OF THE DRAWINGS

FIG. 1 is a schematic diagram illustrating a typical hardware set up while performing a well test in accordance with embodiments of the present disclosure.

FIG. 2 is a graphical representation of a log-log plot showing distortion of computer pressure derivative due to low signal-to-noise ratios in example pressure data.

FIG. 3A is a graphical representation of a log-log plot showing a trend of pressure derivative due to high signal to noise ratios (SNR) in example pressure data in accordance with embodiments of the present disclosure.

FIG. 3B is a graphical representation of an example semi-log plot showing a trend of pressure in example pressure data in accordance with embodiments of the present disclosure.

FIG. 4 is a process flow diagram for forecasting future production rates using well test data that has undergone signal-to-noise ratio analysis in accordance with embodiments of the present disclosure.

FIG. 5 is a process flow diagram for performing a well test using a signal-to-noise ratio data analysis in accordance with embodiments of the present disclosure.

FIG. 6 is a graphical representation of a zoomed-out view of an example entire transient-pressure data of an ongoing transient test in accordance with embodiments of the present disclosure.

FIG. 7 is a graphical representation of example raw noise in pressure data of an ongoing transient pressure test in accordance with embodiments of the present disclosure.

FIG. 8 is a graphical representation of an example spectrum of noise in pressure data of an ongoing transient pressure test in accordance with embodiments of the present disclosure.

FIG. 9 is a graphical representation of an example of amplitudes of noise in pressure data of ongoing transient pressure test in a log-log plot in accordance with embodiments of the present disclosure.

FIG. 10 is a graphical representation of computed signal-to-noise ratios in pressure data of an example on-going transient pressure test in accordance with embodiments of the present disclosure.

FIG. 11 is a schematic diagram of decision demarcation used by a decision monitor to guide intervention of on-going well test data analysis in accordance with embodiments of the present disclosure.

FIG. 12 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The outcome of a well test is dependent on the quality of the signals received. During well tests, transient pressures at active wells are recorded when the wells are producing reservoir fluids or when fluids are injected into the respective reservoirs. Well tests can also be performed during periods when the wells are shut in and the pressures are recorded. Determining signal strengths in pressure data is important during the periods of production, injection and shut in. The shut-in period for a production well is regarded as a build-up period, and that for an injection well is regarded as fall-off period. Normally, the quality of pressure data, when the well is shut in, is much better than the one when is actively producing or injecting. Experimental observations show that the SNR keeps on declining with time when the well is shut in. So, the pressure derivative profile can be constructed with the raw data may fail to demonstrate a clear trend due to the low SNR in the data. This innovation can be utilized in determining the extent of raw pressure data from the build-up or fall-off periods with high SNR for utilization of a pressure-transient analysis. Sometimes observation wells in oil fields monitor pressures for a long time as part of a surveillance program. These pressures may need to be investigated by quantifying signal strengths as well.

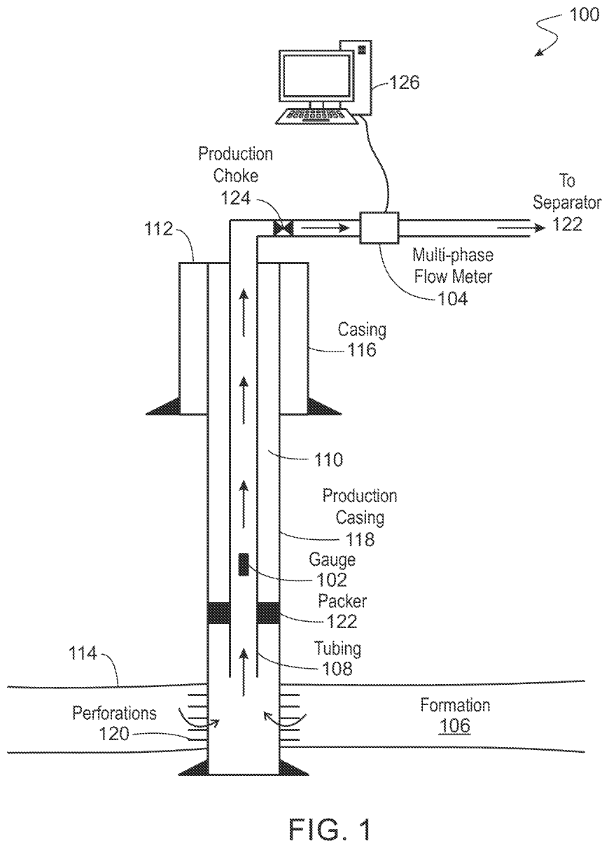

FIG. 1 is a schematic diagram of well system 100 that includes a downhole pressure gauge 102 and multiphase flow meter 104 according to the present disclosure. Generally, FIG. 1 illustrates a portion of an example implementation of a well system 100 according to the present disclosure in which a multiphase fluid, such as a wellbore fluid comprised of one or more of oil, gas, and water, flows through the multiphase flow meter 104.

As shown, the well system 100 accesses a subterranean formation 106 and provides access to hydrocarbons located in such subterranean formation 106. In an example implementation of system 100, the system 100 may be used for a production operation in which the hydrocarbons may be produced from the subterranean formation 106 and flow towards the surface within the wellbore tubing 108 (for example, a production tubing). However, tubing 108 may represent any tubing member positioned in the wellbore 110 such as, for example, coiled tubing, any type of casing, a liner or lining, another downhole tool connected to a work string (in other words, multiple tubulars threaded together), or other form of tubular member.

A drilling assembly (not shown) may be used to form the wellbore 110 extending from the terranean surface 112 and through one or more geological formations in the Earth. One or more subterranean formations, such as subterranean zone 114, are located under the terranean surface 112. One or more wellbore casings, such as a surface casing 116 and production casing 118, may be installed in at least a portion of the wellbore 110. In some embodiments, a drilling assembly used to form the wellbore 110 may be deployed on a body of water rather than the terranean surface 112. For instance, in some embodiments, the terranean surface 112 may be an ocean, gulf, sea, or any other body of water under which hydrocarbon-bearing formations may be found. In short, reference to the terranean surface 112 includes both land and water surfaces and contemplates forming and developing one or more well systems 100 from either or both locations. The wellbore 110 may extend vertically downward towards subterranean zones, like subterranean zone 114. This portion of the wellbore 110 may be enclosed by the production casing 118.

Wellbore fluid (for example, multiphase fluids) can flow through perforations 120 in the subterranean formation 106 towards the terranean surface 112 via wellbore tubing 108, through the multiphase flow meter 104, and to a separator 122. Separator 122 separates the constituents of the wellbore fluid into, for instance, separate flows of oil, gas, and water. However, as the wellbore fluid flows through the multiphase flow meter 104, the wellbore fluid is still a multiphase mixture of oil, gas, and water. In some aspects, the multiphase flow meter 104 is an ultrasonic tomographic multiphase flow meter 104 which measures the ultrasonic waveforms though transducer pairs of the meter. Other types of multiphase flow meters can also be used. A production choke 124 can be used to maintain pressure of the wellbore fluid.

For example, because gas and liquid with obvious density and sound velocity difference have well-recognized characteristics, and its non-radioactive and non-intrusive nature, a multiphase flow meter 104 can be applied in multiphase flow metering. Various experimental mechanisms can achieve some aspects of flow metering, for example, water-cut, void fraction, flow regime detection, etc.

FIG. 1 illustrates a typical hardware set up while performing a well test. This shows that the transient pressure data is recorded at the downhole pressure gauge 102, while a flow-rate measuring device (e.g., multi-phase flow meter 104) at terranean surface 112 gathers detailed flow rates with time. Sometimes, raw data out of the electrical submersible pump in an oil well can be utilized to estimate detailed production rates. In either way, the transient pressure and the corresponding transient rate are always inter-dependent at a given time. These inter-dependent measurements of pressure and flow rates are subject to the traditional pressure-transient analysis. The pressure-transient analysis does not provide the well and reservoir parameters with certainty if the pressure data does not have enough signal strength.

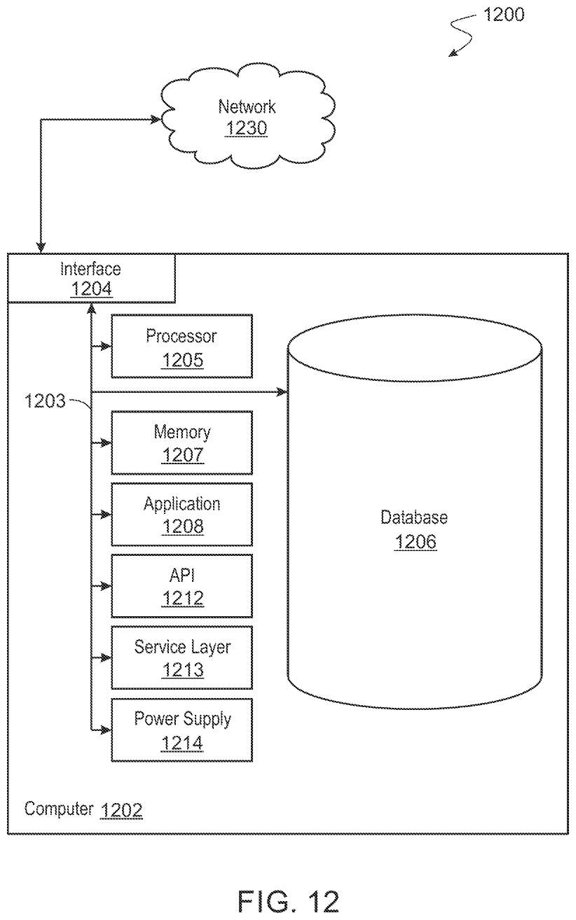

FIG. 1 shows a typical arrangement of a downhole pressure gauge 102 in the wellbore tubing 108. Fluid from the subterranean formation 106 enters the bottom section of the production casing 118 through the perforations 120. This fluid channels through the wellbore tubing 108 which is isolated from the production casing 118 with a packer. As the fluid passes by the downhole pressure gauge 102 to let the pressures recorded downhole at the downhole pressure gauge 102, and flows to the surface, the produced fluid stream passes through a production-rate measuring device (e.g., multi-phase flow meter 104) for the production rate to be measured. A computer 126 can receive data, including raw data from downhole pressure gauge 102 and from multi-phase flowmeter 104. The computer 126 can process the data to determine whether a threshold SNR of the data is met. The computer 126 can then perform pressure-transient analyses, compute well and reservoir parameters, build reservoir simulations, and forecast future production rates. Computer 126 can be similar to computer system 1200 of FIG. 12.

The pressure data collected by the downhole pressure gauge 102 of a transient test can be significantly affected by subtle non-reservoir noise generated by natural or operational factors. Noise is any disturbance, usually originating from the external sources outside the reservoir or the shortcomings of measurement devices (e.g., downhole pressure gauge 102), which would degrade the quality of the desired pressure signal. The impact of noise on the pressure-transient analysis can be evaluated using the signal-to-noise ratios (SNR) achieved during transient tests. Often, a misleading interpretation of the reservoir characteristics can result because of high noise.

This disclosure quantifies effects of noise in the raw data by evaluating the SNR as in wireline testing operations, deep transient testing, drill-stem testing, and production testing, as well as other ways of collected pressure data. This disclosure describes systems and techniques to estimate the SNR as a measure of the strength of the desired pressure signal relative to its undesired component or the noise. By monitoring the SNR, it can be determined if the current noise level is impacting the quality of the pressure data so much that it distorts the computed pressure derivatives and the trend thereof. This knowledge may trigger a corrective action during an ongoing test.

But the measured well pressures in the well testing field pose a significant challenge as both the signal and the noise are convoluted in the captured pressure data simultaneously. This fact makes it difficult to segregate their relative magnitudes at a given time. Note that too much smoothening of pressure data can reduce the appearance of noise in data at a cost of potentially leaving valuable reservoir signals in the raw data diminished.

Disruptive behaviors of hardware and nature tend to distort the measurements performed during such tests. Depending on the amount of disruption caused in the measurements during the tests, there are situations when the test objectives may not be achieved at all. Failure to create dominant reservoir responses can manifest as any insufficient SNR of the captured pressure data in response to the rate of production in the given reservoir system. The SNR is also a function of formation and fluid properties and/or mechanical environment. Effects of noise can be difficult to identify, and often may lead to misrepresentations or misinterpretations. These are quantitatively evaluated in this disclosure to identify the data points with weak signal strengths, which are failing to conclude for any meaningful reservoir characterization. Otherwise, wrongful identification of flow regimes from misleading pressure-derivative profiles can derail a fair analysis of the test data. Experimental data show that the quality of the signal in the test data cannot always be ensured by reviewing on the ordinary Cartesian or history plots. A proper design and execution of a test program considering the effects of noise as discussed earlier can lead to gathering meaningful data.

To compute the signal-to-noise ratio, γ(t), at a given time, the following equation is employed for each data point:

$$γ ( t ) = \frac{\overline{p} - {p}_{w} ( t )}{δ p ( t )} . \qquad ( 1 )$$

where p̅ is the initial reservoir pressure or the average reservoir pressure; p_{w}(t) is the current flow or build-up pressure or just the raw pressure at elapsed time, t; and δp is the amplitude of noise at elapsed time, t, in the raw pressure data. In this disclosure document, δp(t) is simply regarded as the amplitude of noise in the raw pressure data. The real-time pressure, p_{w}(t), and the amplitude of noise, δp(t), may continuously vary from one data point to the next one, and so on. Note that δp(t)=0, if there is no noise at that given time. All non-zero values of δp(t) are regarded positive. As such, Equation (1) indicates that the signal-to-noise ratio, γ(t), may continue to vary with elapsed time due to the variation of the well pressure, p_{w}(t), although the reservoir pressure, p̅, may hold steady during the test duration. Note that the well pressure, p_{w}(t), is captured at a location of the downhole pressure gauge 102 in the subject well. It is normal that p̅ may not be available during the real-time determination of the signal strength because this is an output reservoir parameter after the same set of raw pressure data has been analyzed through the traditional pressure-transient analysis. If so, p̅ needs to be assumed during the initial assessment of the signal strengths. At a later stage, once p̅ is evaluated from the pressure-transient analysis of the same set of raw pressure data with certainty, then the automated workflow is followed through to update the signal-to-noise ratio, γ, with the updated p̅ value. Eventually, all the SNR values, γ(t), from Equation 1 are reported as non-negative.

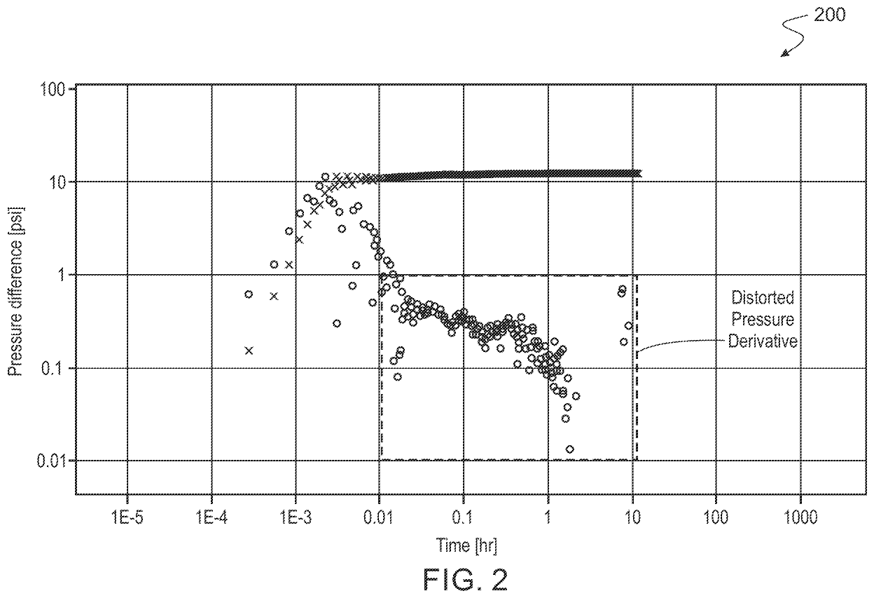

Experimental observations reveal that the magnitudes of SNR influence the trend of pressure-derivative profile. FIG. 2 is a graphical representation 200 of a log-log plot showing distortion of computed pressure derivative due to low signal-to-noise ratios in example pressure data. FIG. 2 displays a log-log plot of pressure derivative and pressure difference in two tracks during a build-up period of 12 hours as constructed from a set of raw transient-pressure data. This data has been subject to low SNR, causing the noisy pressure derivative. Accordingly, the late-time stabilization of the derivative profile cannot be determined with certainty. The diagnostic and interpretive value of the pressure data has not been captured in the given set of data, and this requires a re-run of the well test. Had the data been guided by a criterion of the SNR, the quality of the data could have been improved to be useful in determining the well and the reservoir properties as desired. Thus, the objective of knowing the signal strengths in pressure data is to prevent from such misfortune by introducing a corrective action in advance.

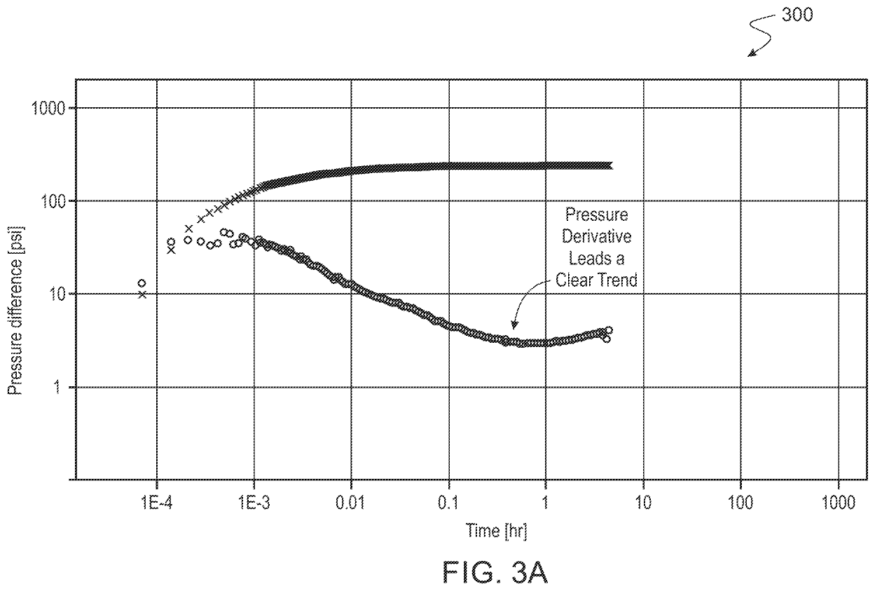

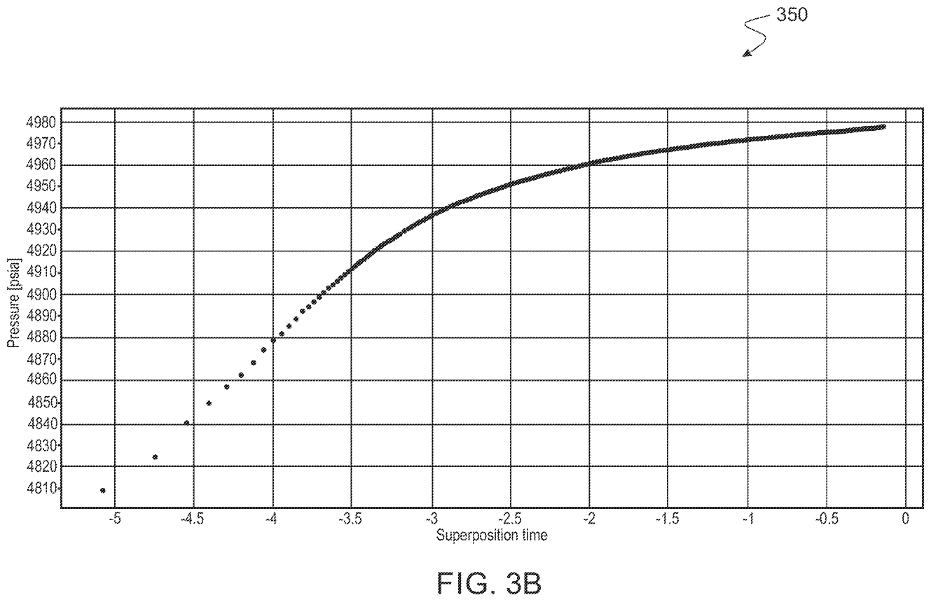

In contrast, the build-up data presented in the log-log plot in FIG. 3A is dominated by the data with high SNR. As a result, the pressure derivative profile portrays a clear trend so that the well and the reservoir can be characterized with certainty. FIG. 3A is a graphical representation 300 of a log-log plot showing a trend of pressure derivative due to high signal to noise ratios in example pressure data in accordance with embodiments of the present disclosure.

FIG. 3B is a graphical representation of an example semi-log plot 350 showing a trend of pressure in example pressure data in accordance with embodiments of the present disclosure. The semi-log plot 350 can be constructed to illustrate graphically the pressure over the logarithmic time function. The semi-log plot 350 can also be susceptible to noise.

If there are multiple measurement devices or gauges installed at different locations of the well or in the reservoir, such multiple sets of measured pressures can be subject to real-time processing individually for determining the signal strengths in parallel with this methodology. For example, pressures in active probes and observation probes of formation testers can be monitored simultaneously for the individual signal strengths.

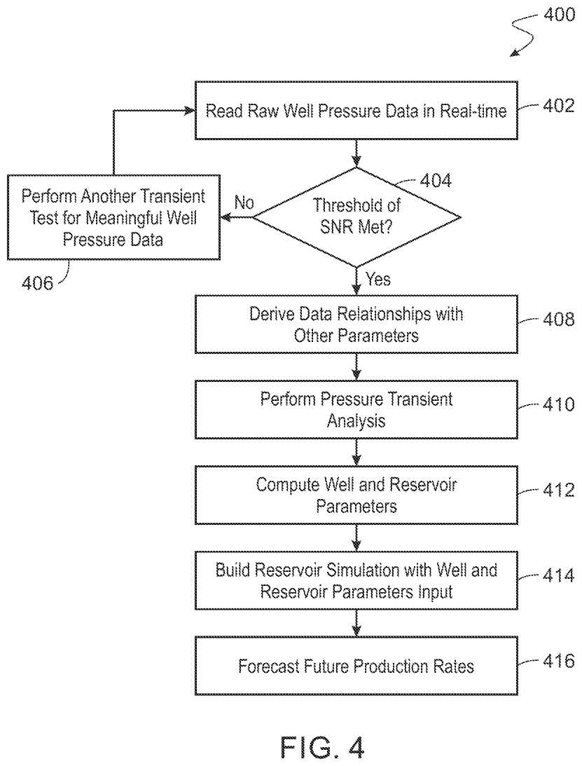

FIG. 4 is a process flow diagram 400 for forecasting future production rates using well test data that has undergone signal-to-noise ratio analysis in accordance with embodiments of the present disclosure. The flow chart in FIG. 4 illustrates the due role of the techniques described herein, in assessing the SNR in the raw pressure data. When the SNR meet or exceed the preset threshold value, the raw pressure data would most likely have the quality to meet the objectives of testing the well. This disclosure provides techniques and system for determining if a given set of raw data has an SNR higher than the threshold value. Persons skilled in the art can readily identify important flow regimes from the derivative profile on a log-log plot. The intercept value of the infinite-acting radial flow regime with a zero slope is particularly utilized for extracting in-situ transmissibility, flow capacity or effective permeability in the reservoir. Once a clear pressure derivative profile has been ascertained, the well and the reservoir parameters can be determined with greater certainty. These parameters influence the reservoir simulation model as the input. A well-built reservoir simulation model provides reliable production forecasts for an economic analysis.

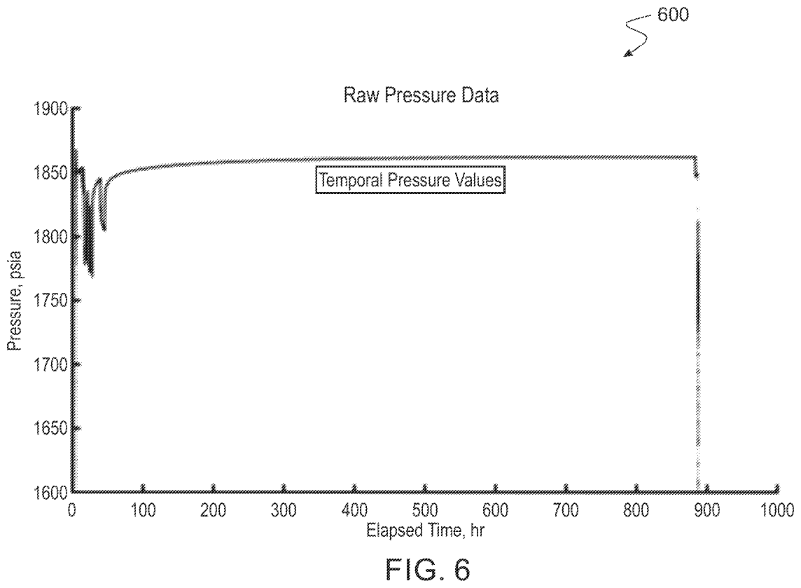

In FIG. 4, at the outset, raw data from a sensor can be read (or received) at a computer system. (402). The raw data can be read from a pressure sensor, such as a downhole pressure gauge 102. The raw data can be read in real-time or near-real-time. Typical raw pressure data may appear as presented in FIG. 6 over the entire test duration. FIG. 6 is a graphical representation 600 of a zoomed-out view of an example entire transient-pressure data of an ongoing transient test in accordance with embodiments of the present disclosure. This zoomed-out view of the entire transient-pressure data does not have the resolution of displaying noise contained in the data.

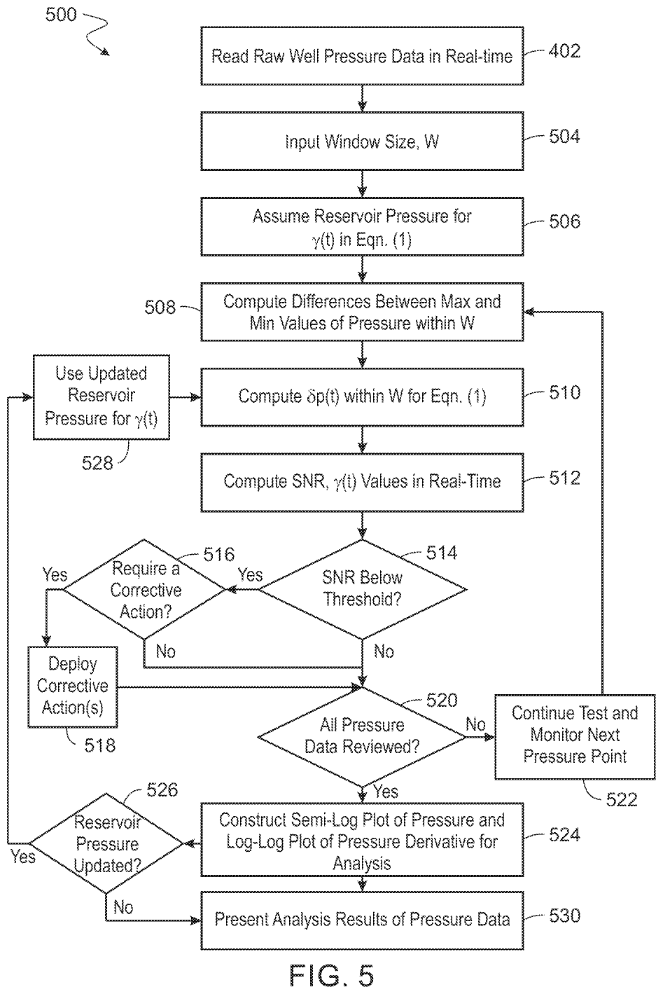

Therefore, a determination can be made of the SNR level after reading the raw data as step 402. For example, the computer system can determine whether the SNR meets or exceeds a threshold value. FIG. 5 is a process flow diagram 500 for determining whether a signal-to-noise ratio meets a threshold value in accordance with embodiments of the present disclosure. As part of quantitative benchmarking of quality assurance/quality control (QA/QC) of the raw pressure data, the computer system can determine how much noise exists in the pressure data in comparison to the signal. FIG. 5 describes the entire process of quantifying the signal strength of raw pressure values in terms of SNR. The flow chart in FIG. 5 summarizes the steps of the automated workflow to be followed for assessing SNR in real-time (or near-real-time) in accordance with embodiments of this disclosure. Essentially, FIG. 5 represents the analysis that is performed when assessing step 404 in FIG. 4. Thus, the following briefly turns to FIG. 5, before returning to the remaining portions of FIG. 4:

As mentioned before, raw pressure data is read in real-time. The computer system 402 can set an input window size W. (504). To increase the processing efficiency, the operator controlling the computer system or performing the well test may decide to process the data within a time window, W, along the time scale, instead of one data point at a time. The window, W, at a given moment contains a number of discrete data points, which is similar to a sampling window. This analysis assumes a value for the initial or the average reservoir pressure in computing γ(t) in Equation (1). (506)

Within the window, W, the computing system can determine the pressure range by identifying the maximum and the minimum values, the difference of which (peak-to-peak value) happens to be twice the magnitude of raw noise. (508) This leads to identifying the mean or central pressure value within the window, and the raw noise is either positive or negative compared to the central pressure value with elapsed time.

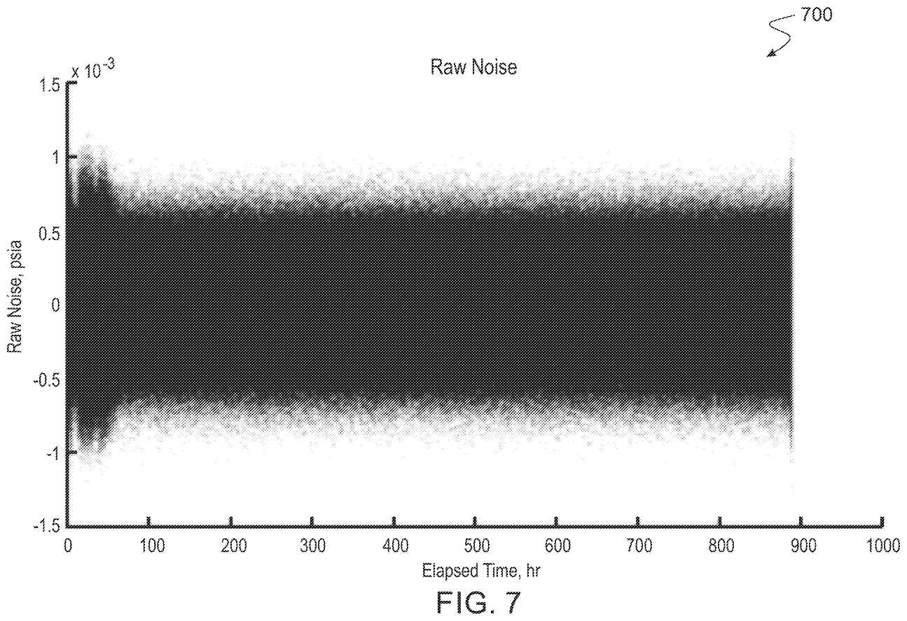

Note that the mean pressure values represent the central tendency of the raw pressure data. Nominally, the noise can be zero, positive or negative. The positive raw noise tends to cause the raw pressure value to be greater than the mean pressure value, and the negative raw noise tends to cause the raw pressure value to be less than the mean pressure value within the window. FIG. 7 is a graphical representation 700 of example raw noise in pressure data of an ongoing transient pressure test in accordance with embodiments of the present disclosure. FIG. 7 presents the positive and the negative raw noise simultaneously in the raw pressure data.

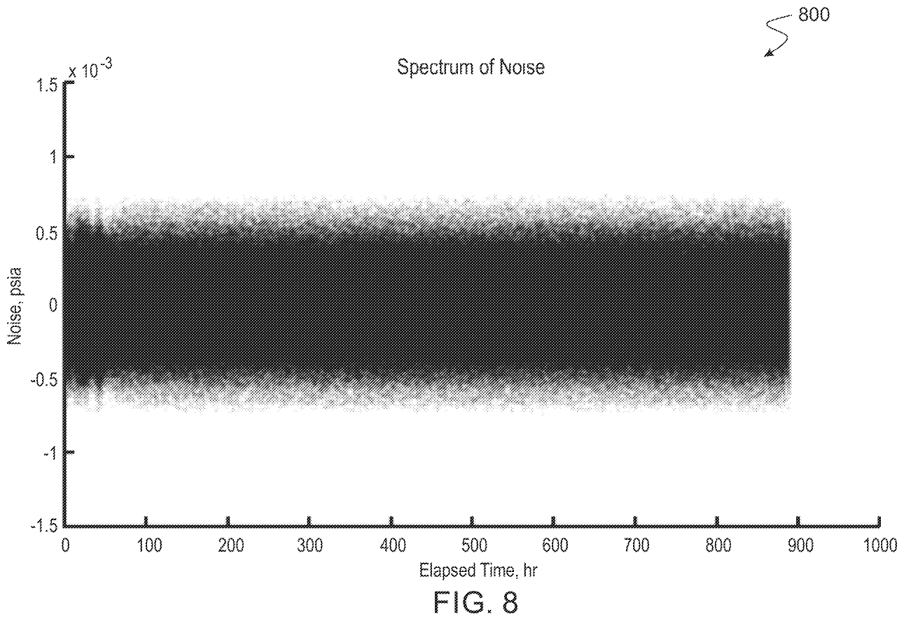

Next step is to smoothen the noise outliers by performing operations of averaging over the window, W. Being in the minority, the outliers in the data are absorbed by the general trend of noise in the averaging process. In addition, the impact of the outliers is significantly dampened, and their influence on the respective noise is minimized. This leads to displaying clear spectrum of noise in the data as shown in FIG. 8. FIG. 8 is a graphical representation 800 of an example spectrum of noise in pressure data of an ongoing transient pressure test in accordance with embodiments of the present disclosure.

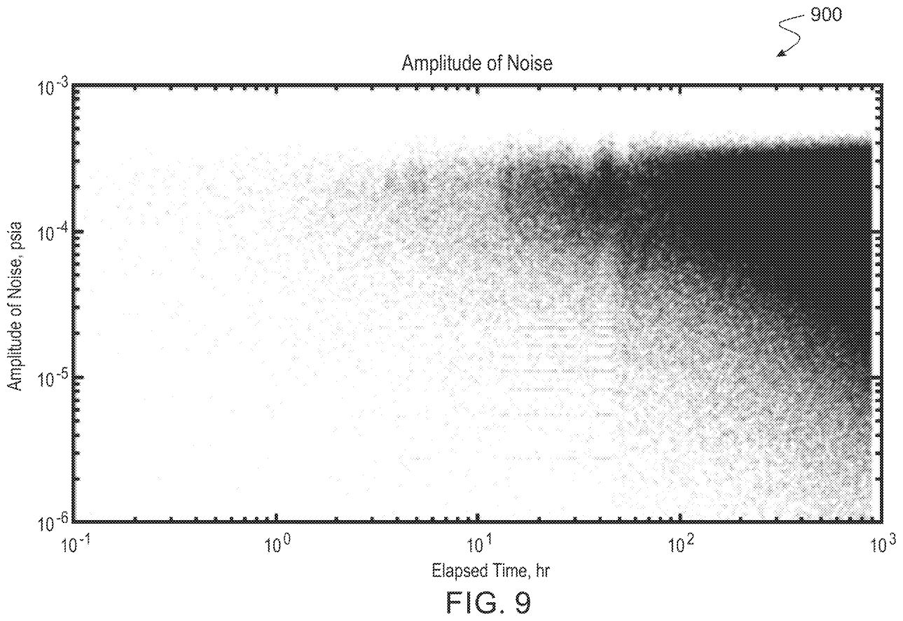

The amplitudes of noise δp(t), presented as non-negative values, are computed by averaging the neighboring magnitudes of noise, including both positive and negative values. (510) In the averaging process, occurrences of consecutive positive and negative values are treated separately without mixing positive and negative values. Each occurrence of consecutive positive or negative values only is identified first. An average of the negative values in an occurrence turns out to be negative. These negative values are designated positive values for consideration as amplitudes of noise. An average of the positive values in an occurrence turns out to be always positive, which is readily designated as amplitudes of noise. Therefore, all the non-zero noise values are turned in as amplitudes of noise, δp. These amplitudes are subsequently presented in the log-log plot of FIG. 9. Based on display preferences, other variations of graphical scales in the axes can be considered to present the same information as in FIG. 9. FIG. 9 is a graphical representation 900 of an example of amplitudes of noise in pressure data of ongoing transient pressure test in a log-log plot in accordance with embodiments of the present disclosure.

The signal-to-noise ratio, γ(t), of each pressure data point can be calculated with Equation 1, once the amplitude of noise, δp(t), has been quantified as non-negative values. (512) At this stage, the analyst may assume the initial or the average reservoir pressure, p̅, for the early assessment of the signal strengths, γ(t). Once p̅ has been determined with certainty with the same set of raw pressure data at a later stage, the entire workflow needs to be repeated for the final values of γ(t). (528) This asserts that sometimes the process can be iterative.

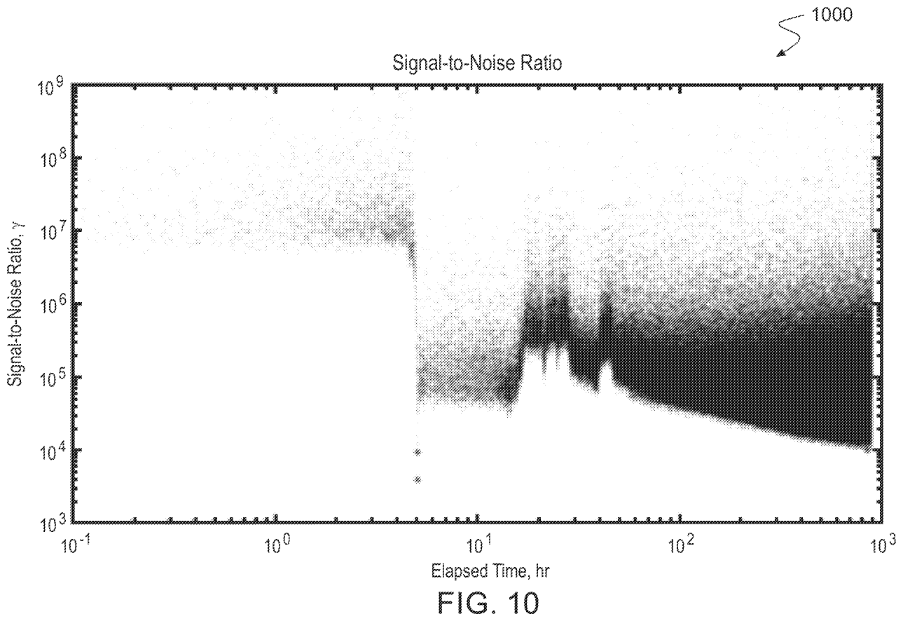

As an example, the average reservoir pressure (p̅) of 1866.8 psia is considered in the presented raw data of FIG. 6. So, this average reservoir pressure, and the presented amplitudes, δp, in FIG. 9 are utilized in Equation 1 to compute the signal-to-noise ratio, γ. As mentioned earlier, the non-zero amplitudes of noise, δp, are regarded non-negative. The computed γ values are presented in the log-log plot of FIG. 10. FIG. 10 is a graphical representation 100 of computed signal-to-noise ratios in pressure data of an example on-going transient pressure test in accordance with embodiments of the present disclosure. In this particular case, the log-log plot has presented the results over the elapsed time in a concise manner. However, the operator may choose to present such results with different kinds of scales on the axes based on their display preferences.

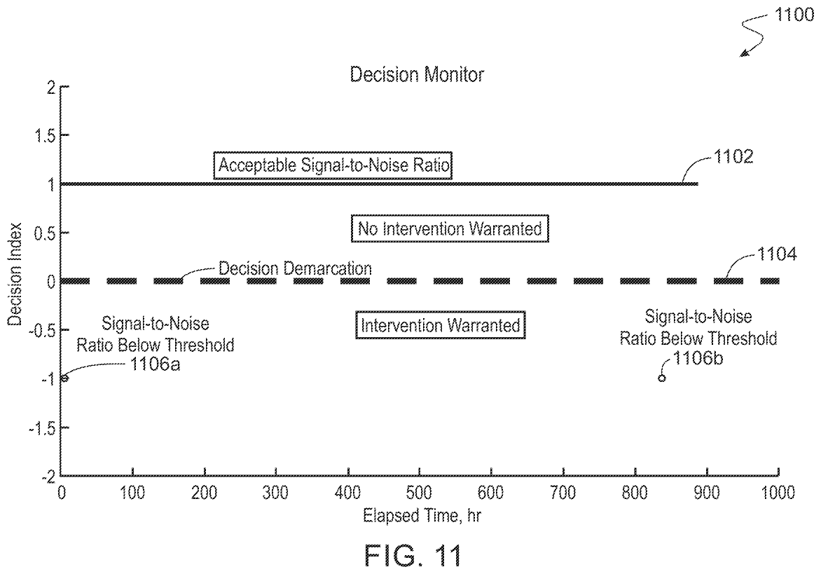

The computed SNR γ (t) can be compared against a threshold value. (514) FIG. 11 is a schematic diagram of decision demarcation guide 1100 used by a decision monitor to guide intervention of on-going well test data analysis in accordance with embodiments of the present disclosure. This guide 1100 advises when to initiate an intervention to the ongoing operations. Such a visual guide helps the operator if they need to invoke any corrective actions.

When the SNR at a given time is above a present “Threshold,” referred to in FIG. 11 as a decision demarcation line 1104, “No Intervention Warranted” applies. When the SNR at a given time falls below the preset “Threshold,” the decision index is assigned as −1 (negative unity), and when the SNR at a given time stays above the “Threshold,” the decision index is assigned as +1 (positive unity). In FIG. 11, the decision index is associated with a decision demarcation line 1104, and SNR above the decision demarcation line 1104 receives an index of 1 associated with an acceptable SNR 1102. A decision index of −1 is assigned to point values below the decision demarcation line 1104, such as points 1106a and 1006b.

The operator of the ongoing well test can designate the “Threshold,” based on their experiences primarily with the measurement devices, reservoir quality, fluid production rates and testing operations. In this example, a value of 10,000 has been designated by the operator for the threshold. So, any SNR value lower than 10,000 are to be flagged for potential intervention. FIG. 10 displays a few asterisks (*), flagging the data points that fell below the threshold value. Assigning a higher threshold looks for a more dominant signal strength in the raw pressure data to ascertain that the extracted well and the reservoir parameters from a pressure-transient analysis of the data are representative of the in-situ or downhole condition. FIG. 11 illustrates decision monitor with the instants of flags. This step concludes the evaluation phase of signal strengths so that the operator can act if any corrective actions are warranted.

If the last SNR is below the threshold value (514), then the operator or analyst performing the well test evaluation can determine whether corrective action is to be implemented. (516) If corrective action is to be taken, then the analyst or operator can initiate the corrective action. (518)

Corrective actions may include one or multiple of the following:

Adjust to higher production or injection rates for higher drawdown in the reservoir. A higher production or injection rate introduces more pressure drawdown or pressure gain around the wellbore. Such prolonged rates will induce larger pressure gradient inside the reservoir to strengthen pressure signals.

Control operational noise. Some of the oilfield activities due to the other adjacent operations may cause electrical and mechanical interference with the testing operations. As such the noise condition during the well testing operations can get worse. This kind of interfering operations need to be minimized so that the noise level in the pressure data does not get worsened.

Schedule the well testing operations to minimize impacts of tides in offshore fields;

Avert multi-phase flow of fluids, especially by not flowing below the bubble-point pressure at the downhole condition for oil wells. Gas wells should not flow below the dew-point pressure at the downhole condition. Flow of multiple phases of oil, water and gas in the production string can distort pressure data.

Deploy gauges with better resolution. This is to make sure that the pressure data does not accumulate any noise due to measurement devices.

Adjust test duration by employing a rigorous test design program. This is to make sure all the flow and buildup periods are well utilized to capture the maximum possible signal strengths in the pressure data.

Keep longer flow or injection periods so that high drawdown or pressure gain can be achieved for increasing the signal strengths in the pressure data.

Place gauges close to reservoir so that any fluid dynamics between the gauge and the reservoir in the wellbore can influence the noise level in the data to a minimum.

Minimize wellbore dynamics during shut in. A downhole shut-in tool can be deployed to reduce the effective wellbore volume when the well is shut in for a buildup or falloff test. This would minimize the distortion of pressure data due to the wellbore storage phenomenon.

Following the corrective actions, the testing operations can resume with improved SNR in the data. As the fresh pressure data starts coming in, the monitoring of the SNR also resumes as before. If no corrective action is to take place, even if the SNR is below the threshold, then the process can proceed by determining if all pressure data has been evaluated. (520) If not, then continue test and monitoring for the next pressure point. (522) Return to step (508).

If all pressure data has been reviewed (520), then the semi-log plot of pressure (e.g., FIG. 3A) and log-log plot of pressure derivate (e.g., as in FIG. 3B) can be constructed for analysis. (524) With the scrutinized raw pressure data, the reservoir pressure value can be updated. (526) With that updated pressure information, the non-zero amplitudes of noise, δp can be recomputed (510) using the updated reservoir pressure for γ(t). (528)

If no updates are necessary at (526), the final results can be presented. (530) The final results can then be used by operator/analyst later for simulation and prediction purposes.

Returning to FIG. 4, the above process can be encapsulated by the determination made in (404). If the threshold SNR is not met for a quantity of data such that the data is not useable, another transient test can be performed to obtain meaningful data. (406) For example, after determining the SNR for all data points, a decision can be made whether the SNR is below a threshold value for some threshold percentage of data points, such that the resulting analysis would not provide statistically meaningful results. If that condition is true, then the pressure test can be performed again and new raw data can be read in real-time. (402)

If the SNR thresholds are met (or met for a statistically relevant number of data points), the computer system can derive data relationships with other parameters. (408) For example, a detailed measurement of well pressure vs time can be assessed, high resolution production/injection rates vs time can be assessed, petrophysical parameters can be determined, and fluid properties can be determined. The parameters can be used together (in some combination of one or more of the aforementioned relationships) for performing pressure-transient analysis. (410) From the pressure-transient analysis, the computing system can compute well and reservoir parameters. (412) From the well and reservoir parameters, the computing system can build a reservoir simulation. (414) The simulation can be used to forecast future production rates for the reservoir (e.g., by an analyst operating the simulation on the computer system). (416)

### NOMENCLATURE

p_{w} Raw downhole pressure during flow or shut in at a given elapsed time, psia
p̅ Initial or average reservoir pressure, psia
δp Amplitude of noise in pressure data [zero or positive], psia
t Current elapsed time, hr
SNR Signal-to-noise ratio
γ(t) Signal-to-noise ratio for a given time (e.g., hours).

FIG. 12 is a block diagram of an example computer system 1200 used to provide computational functionalities associated with described algorithms, methods, functions, processes, flows, and procedures described in the present disclosure, according to some implementations of the present disclosure. The illustrated computer 1202 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1202 can include input devices such as keypads, keyboards, and touch screens that can accept user information. Also, the computer 1202 can include output devices that can convey information associated with the operation of the computer 1202. The information can include digital data, visual data, audio information, or a combination of information. The information can be presented in a graphical user interface (UI) (or GUI).

The computer 1202 can serve in a role as a client, a network component, a server, a database, a persistency, or components of a computer system for performing the subject matter described in the present disclosure. The illustrated computer 1202 is communicably coupled with a network 1230. In some implementations, one or more components of the computer 1202 can be configured to operate within different environments, including cloud-computing-based environments, local environments, global environments, and combinations of environments.

At a top level, the computer 1202 is an electronic computing device operable to receive, transmit, process, store, and manage data and information associated with the described subject matter. According to some implementations, the computer 1202 can also include, or be communicably coupled with, an application server, an email server, a web server, a caching server, a streaming data server, or a combination of servers.

The computer 1202 can receive requests over network 1230 from a client application (for example, executing on another computer 1202). The computer 1202 can respond to the received requests by processing the received requests using software applications. Requests can also be sent to the computer 1202 from internal users (for example, from a command console), external (or third) parties, automated applications, entities, individuals, systems, and computers.

Each of the components of the computer 1202 can communicate using a system bus 1203. In some implementations, any or all of the components of the computer 1202, including hardware or software components, can interface with each other or the interface 1204 (or a combination of both) over the system bus 1203. Interfaces can use an application programming interface (API) 1212, a service layer 1213, or a combination of the API 1212 and service layer 1213. The API 1212 can include specifications for routines, data structures, and object classes. The API 1212 can be either computer-language independent or dependent. The API 1212 can refer to a complete interface, a single function, or a set of APIs.

The service layer 1213 can provide software services to the computer 1202 and other components (whether illustrated or not) that are communicably coupled to the computer 1202. The functionality of the computer 1202 can be accessible for all service consumers using this service layer. Software services, such as those provided by the service layer 1213, can provide reusable, defined functionalities through a defined interface. For example, the interface can be software written in JAVA, C++, or a language providing data in extensible markup language (XML) format. While illustrated as an integrated component of the computer 1202, in alternative implementations, the API 1212 or the service layer 1213 can be stand-alone components in relation to other components of the computer 1202 and other components communicably coupled to the computer 1202. Moreover, any or all parts of the API 1212 or the service layer 1213 can be implemented as child or sub-modules of another software module, enterprise application, or hardware module without departing from the scope of the present disclosure.

The computer 1202 includes an interface 1204. Although illustrated as a single interface 1204 in FIG. 12, two or more interfaces 1204 can be used according to particular needs, desires, or particular implementations of the computer 1202 and the described functionality. The interface 1204 can be used by the computer 1202 for communicating with other systems that are connected to the network 1230 (whether illustrated or not) in a distributed environment. Generally, the interface 1204 can include, or be implemented using, logic encoded in software or hardware (or a combination of software and hardware) operable to communicate with the network 1230. More specifically, the interface 1204 can include software supporting one or more communication protocols associated with communications. As such, the network 1230 or the interface's hardware can be operable to communicate physical signals within and outside of the illustrated computer 1202.

The computer 1202 includes a processor 1205. Although illustrated as a single processor 1205 in FIG. 12, two or more processors 1205 can be used according to particular needs, desires, or particular implementations of the computer 1202 and the described functionality. Generally, the processor 1205 can execute instructions and can manipulate data to perform the operations of the computer 1202, including operations using algorithms, methods, functions, processes, flows, and procedures as described in the present disclosure.

The computer 1202 also includes a database 1206 that can hold data for the computer 1202 and other components connected to the network 1230 (whether illustrated or not). For example, database 1206 can be an in-memory, conventional, or a database storing data consistent with the present disclosure. In some implementations, database 1206 can be a combination of two or more different database types (for example, hybrid in-memory and conventional databases) according to particular needs, desires, or particular implementations of the computer 1202 and the described functionality. Although illustrated as a single database 1206 in FIG. 12, two or more databases (of the same, different, or combination of types) can be used according to particular needs, desires, or particular implementations of the computer 1202 and the described functionality. While database 1206 is illustrated as an internal component of the computer 1202, in alternative implementations, database 1206 can be external to the computer 1202.

The computer 1202 also includes a memory 1207 that can hold data for the computer 1202 or a combination of components connected to the network 1230 (whether illustrated or not). Memory 1207 can store any data consistent with the present disclosure. In some implementations, memory 1207 can be a combination of two or more different types of memory (for example, a combination of semiconductor and magnetic storage) according to particular needs, desires, or particular implementations of the computer 1202 and the described functionality. Although illustrated as a single memory 1207 in FIG. 12, two or more memories 1207 (of the same, different, or combination of types) can be used according to particular needs, desires, or particular implementations of the computer 1202 and the described functionality. While memory 1207 is illustrated as an internal component of the computer 1202, in alternative implementations, memory 1207 can be external to the computer 1202.

The application 1208 can be an algorithmic software engine providing functionality according to particular needs, desires, or particular implementations of the computer 1202 and the described functionality. For example, application 1208 can serve as one or more components, modules, or applications. Further, although illustrated as a single application 1208, the application 1208 can be implemented as multiple applications 1208 on the computer 1202. In addition, although illustrated as internal to the computer 1202, in alternative implementations, the application 1208 can be external to the computer 1202.

The computer 1202 can also include a power supply 1214. The power supply 1214 can include a rechargeable or non-rechargeable battery that can be configured to be either user- or non-user-replaceable. In some implementations, the power supply 1214 can include power-conversion and management circuits, including recharging, standby, and power management functionalities. In some implementations, the power-supply 1214 can include a power plug to allow the computer 1202 to be plugged into a wall socket or a power source to, for example, power the computer 1202 or recharge a rechargeable battery.

There can be any number of computers 1202 associated with, or external to, a computer system containing computer 1202, with each computer 1202 communicating over network 1230. Further, the terms “client,” “user,” and other appropriate terminology can be used interchangeably, as appropriate, without departing from the scope of the present disclosure. Moreover, the present disclosure contemplates that many users can use one computer 1202 and one user can use multiple computers 1202.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method comprising:
performing a well test on a well, the well comprising a subterranean wellbore with a tubular;
receiving, by a computer system, raw data from a pressure gauge residing within the tubular, the raw data comprising discrete pressure values in a time series for a fluid flowing through the tubular;
determining, by the computer system, an amplitude of noise for each pressure value in a time series;
computing, by the computer system, signal-to-noise ratio for each pressure value in a time series based on the determined amplitude;
comparing, by the computer system, the signal-to-noise ratio against a predetermined threshold value for each pressure value in a time series;
for each pressure value in a time series, determining, by the computer system, whether the signal-to-noise ratio is above or below the predetermined threshold value;
constructing, by the computer system, a simulation of the well based on the signal-to-noise ratio for each pressure value in a time series being above the predetermined threshold value; and
forecasting, by the computer system, future production rates for the well using the simulation.

2. The computer-implemented method of claim 1, further comprising:
for each pressure value in a time series, determining, by the computer system, that the signal-to-noise ratio is below the predetermined threshold value; and
for each pressure value in a time series, performing a corrective action to address the signal-to-noise ratio being below the predetermined threshold value.

3. The computer-implemented method of claim 2, wherein the corrective action comprises one or more of:
adjust to higher production or injection rates for higher drawdown in the reservoir;
control operational noise;
schedule to minimize impacts of tides in offshore fields;
avert multi-phase flow of fluids;
deploy gauges with better resolution;
adjust test duration;
keep longer flow or injection periods;
place gauges close to reservoir; and
minimize wellbore dynamics during shut in.

4. The computer-implemented method of claim 1, further comprising defining a sampling window W to establish a subset of raw data for calculating signal-to-noise ratio for the pressure value in a time series.

5. The computer-implemented method of claim 4, further comprising:
for an assumed pressure of the well in a time series, determining maximum and minimum values of the pressure value in a time series for pressure values within the window W, and wherein determining the amplitude of the noise comprises determining the amplitude of the noise from the minimum and maximum pressure values within the window W.

6. The computer-implemented method of claim 1, further comprising constructing a log-log plot of a pressure derivative profile based on the computed signal-to-noise ratio for each pressure value in a time series.

7. The computer-implemented method of claim 6, further comprising performing a pressure-transient analysis using the pressure derivate profile.

8. A non-transitory, computer-readable medium storing one or more instructions executable by a computer system to perform operations comprising:
performing a well test on a well, the well comprising a subterranean wellbore with a tubular;
receiving, by a computer system, raw data from a pressure gauge residing within the tubular, the raw data comprising a pressure value in a time series for a fluid flowing through the tubular;
determining, by the computer system, an amplitude of noise for each pressure value in a time series;
computing, by the computer system, signal-to-noise ratio for each pressure value in a time series based on the determined amplitude;
comparing, by the computer system, the signal-to-noise ratio against a predetermined threshold value for each pressure value in a time series;
for each pressure value in a time series, determining, by the computer system, whether the signal-to-noise ratio is above or below the predetermined threshold value;
constructing, by the computer system, a simulation of the well based on the signal-to-noise ratio for each pressure value in a time series being above the predetermined threshold value; and
forecasting, by the computer system, future production rates for the well using the simulation.

9. The non-transitory, computer-readable medium of claim 8, the operations further comprising:
for each pressure value in a time series, determining, by the computer system, that the signal-to-noise ratio is below the predetermined threshold value; and
for each pressure value in a time series, performing a corrective action to address the signal-to-noise ratio being below the predetermined threshold value.

10. The non-transitory, computer-readable medium of claim 9, the operations further comprising one or more of:
adjust to higher production or injection rates for higher drawdown in the reservoir;
control operational noise;
schedule to minimize impacts of tides in offshore fields;
avert multi-phase flow of fluids;
deploy gauges with better resolution;
adjust test duration;
keep longer flow or injection periods;
place gauges close to reservoir; and
minimize wellbore dynamics during shut in.

11. The non-transitory, computer-readable medium of claim 8, the operations further comprising defining a sampling window W to establish a subset of raw data for calculating signal-to-noise ratio for the pressure value in a time series.

12. The non-transitory, computer-readable medium of claim 11, the operations further comprising:
for an assumed pressure of the well in a time series, determining maximum and minimum values of the pressure value in a time series for pressure values within the window W, and wherein determining the amplitude of the noise comprises determining the amplitude of the noise from the minimum and maximum pressure values within the window W.

13. The non-transitory, computer-readable medium of claim 8, the operations further comprising constructing a log-log plot of a pressure derivative profile based on the computed signal-to-noise ratio for each pressure value in a time series.

14. The non-transitory, computer-readable medium of claim 13, the operations further comprising performing a pressure-transient analysis using the pressure derivate profile.

15. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
performing a well test on a well, the well comprising a subterranean wellbore with a tubular;
receiving, by a computer system, raw data from a pressure gauge residing within the tubular, the raw data comprising a pressure value in a time series for a fluid flowing through the tubular;
determining, by the computer system, an amplitude of noise for each pressure value in a time series;
computing, by the computer system, signal-to-noise ratio for each pressure value in a time series based on the determined amplitude;
comparing, by the computer system, the signal-to-noise ratio against a predetermined threshold value for each pressure value in a time series;
for each pressure value in a time series, determining, by the computer system, whether the signal-to-noise ratio is above or below the predetermined threshold value;
constructing, by the computer system, a simulation of the well based on the signal-to-noise ratio for each pressure value in a time series being above the predetermined threshold value; and
forecasting, by the computer system, future production rates for the well using the simulation.

16. The system of claim 15, the operations further comprising:
for each pressure value in a time series, determining, by the computer system, that the signal-to-noise ratio is below the predetermined threshold value; and
for each pressure value in a time series, performing a corrective action to address the signal-to-noise ratio being below the predetermined threshold value.

17. The system of claim 16, the operations further comprising one or more of:
adjust to higher production or injection rates for higher drawdown in the reservoir;
control operational noise;
schedule to minimize impacts of tides in offshore fields;
avert multi-phase flow of fluids;
deploy gauges with better resolution;
adjust test duration;
keep longer flow or injection periods;
place gauges close to reservoir; and
minimize wellbore dynamics during shut in.

18. The system of claim 15, the operations further comprising defining a sampling window W to establish a subset of raw data for calculating signal-to-noise ratio for the pressure value in a time series.

19. The system of claim 18, the operations further comprising:
for an assumed pressure of the well in a time series, determining maximum and minimum values of the pressure value in a time series for pressure values within the window W, and wherein determining the amplitude of the noise comprises determining the amplitude of the noise from the minimum and maximum pressure values within the window W.

20. The system of claim 15, the operations further comprising constructing a log-log plot of a pressure derivative profile based on the computed signal-to-noise ratio for each pressure value in a time series; and
performing a pressure-transient analysis using the pressure derivate profile.
